(19) United States
(12) Patent Application Publication
(10) Pub. No.: US 2002/0086519 A1
(43) Pub. Date: Jul. 4, 2002

(54) Stacked vias and method

(76) Inventors: Theodore W. Houston, Richardson, TX (US); Thomas D. Bonifield, Dallas, TX (US)

Correspondence Address: TEXAS INSTRUMENTS INCORPORATED, P O BOX 655474, M/S 3999, DALLAS, TX, 75265

(21) Appl. No.: 10/061,540

(22) Filed: Oct. 25, 2001

Related U.S. Application Data
(60) Provisional application No. 60/258,879, filed on Dec. 29, 2000.

(51) Int. Cl. H01L 21/4763; H01L 21/44; H01L 23/48; H01L 23/52; H01L 29/40

(52) U.S. Cl. 438/622; 438/618; 438/637; 438/638; 438/672; 257/760; 257/775

(57) ABSTRACT

A method is provided for forming stacked vias (28, 44) in an integrated circuit that includes providing a first dielectric layer (10) comprising a interconnect element (12). A second dielectric layer (14) is formed outwardly of the first dielectric layer (10). The second dielectric layer (14) comprises a via layer (14a) and an interconnect layer (14b). A first via opening (20) is formed by removing a portion of the second dielectric layer (14) to expose the interconnect element (12). A first via (28) is formed in the first via opening (20). A second via (44) is formed outwardly of the first via (28). The second via (44) is directly coupled to the first via (28).

### TECHNICAL FIELD OF THE INVENTION

This invention relates generally to semiconductor manufacturing and more particularly to improved stacked vias and method.

### BACKGROUND OF THE INVENTION

Modern electronic equipment such as televisions, telephones, radios and computers are generally constructed of solid state devices. Integrated circuits are preferred in electronic equipment because they are extremely small and relatively inexpensive. Additionally, integrated circuits are very reliable because they have no moving parts, but are based on the movement of charge carriers.

Integrated circuits may include transistors, capacitors, resistors, interconnects and other semiconductor devices. Typically, such devices are fabricated on a substrate and interconnected to form memory arrays, logic structures, timers and other components of an integrated circuit.

These components, including interconnects, are formed on several different levels over a substrate. Components on different levels may be interconnected with each other through vias which provide electrical connections from one layer of components to another. If two components are separated by intervening levels of components, they may be interconnected with each other through a stacked via which provides an electrical connection from a component in one layer, through a metal element in an intervening layer, to a component in yet another layer.

Because the metal element in the intervening layer is patterned and etched along with other components in the intervening layer, the metal element connecting two vias to form a conventional stacked via has a minimum size corresponding to minimum area rules for patterning components in interconnect levels. These minimum area rules result from the lithographic and processing constraints to accurately form elements of varied sizes with the same patterning step. In contrast, the lithography and processing of more uniform-sized elements, such as vias, can be optimized to allow the formation of reduced-area elements. Thus, in a conventional via stack, the size of the interconnect element, which is larger than the vias, limits the density of components in the integrated circuit.

A conventional method for forming such a via stack involves a dual damascene process. The dual damascene process includes the formation of a via and an interconnect element through a dielectric layer that may comprise multiple layers of different materials with different etch properties. A via pattern is etched through the full dielectric layer and an interconnect pattern is etched partially through the dielectric layer. The via pattern, which is generally a standard area, is overlapped with the interconnect pattern that is a larger area than the via pattern in order to provide margin for misalignment between the via pattern and the interconnect pattern and in order to improve the aspect ratio for fill of the via. The trenches which are formed by the via etch or the interconnect etch are then filled with metal and the metal is planarized down to the outer surface of the dielectric layer by chemical mechanical polish to complete the dual damascene process.

### SUMMARY OF THE INVENTION

In accordance with the present invention, improved stacked vias and method are provided that substantially eliminate or reduce disadvantages and problems associated with previously developed systems and methods. In particular, the present invention provides a stacked via without an intervening interconnect element, thereby allowing an increase in the density of the corresponding integrated circuit.

In one embodiment of the present invention, a method is provided for forming stacked vias in an integrated circuit includes providing a first dielectric layer comprising a interconnect element. A second dielectric layer is formed outwardly of the first dielectric layer. The second dielectric layer comprises a via layer and an interconnect layer. A first via opening is formed by removing a portion of the second dielectric layer to expose the interconnect element. A first via is formed in the first via opening. A second via is formed outwardly of the first via. The second via is directly coupled to the first via.

In another embodiment of the present invention, an integrated circuit comprising a stacked via is provided. The stacked via includes a first via and a second via. The first via is formed through a first dielectric layer. The first dielectric layer includes a via layer and an interconnect layer and is formed outwardly of a second dielectric layer comprising a interconnect element. The first via is directly coupled to the interconnect element. The second via is formed through a third dielectric layer that is formed outwardly of the first dielectric layer. The second via is directly coupled to the first via.

Technical advantages of the present invention include providing improved stacked vias. In a particular embodiment, a stacked via includes a first via through both a via layer and an interconnect layer, in addition to a second via through another via layer. As a result, no intervening interconnect element needs to be patterned and etched into the interconnect layer in order to interconnect the two vias. Accordingly, the density of the corresponding integrated circuit is increased as the vias require less space than an interconnect element. In addition, the capacitance of the node including the via is reduced.

Other technical advantages will be readily apparent to one skilled in the art from the following figures, description, and claims.

### BRIEF DESCRIPTION OF THE DRAWINGS

For a more complete understanding of the present invention and its advantages, reference is now made to the following description taken in conjunction with the accompanying drawings, wherein like numerals represent like parts, in which:

FIGS. 1A-K are a series of schematic cross-sectional diagrams illustrating a method for forming stacked vias on a semiconductor wafer in accordance with one embodiment of the present invention.

### DETAILED DESCRIPTION OF THE INVENTION

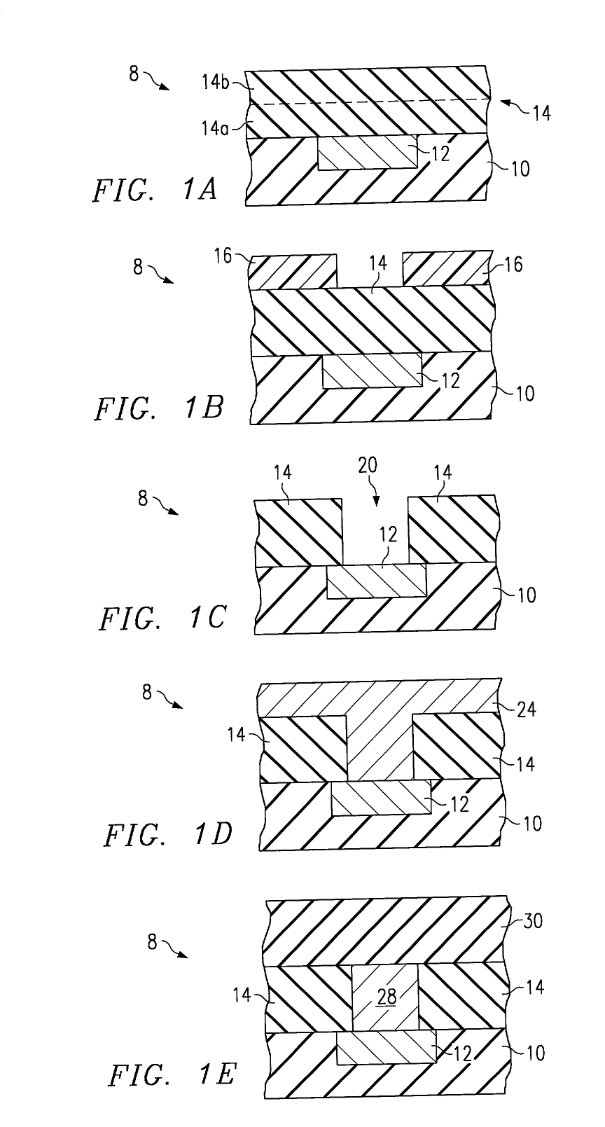

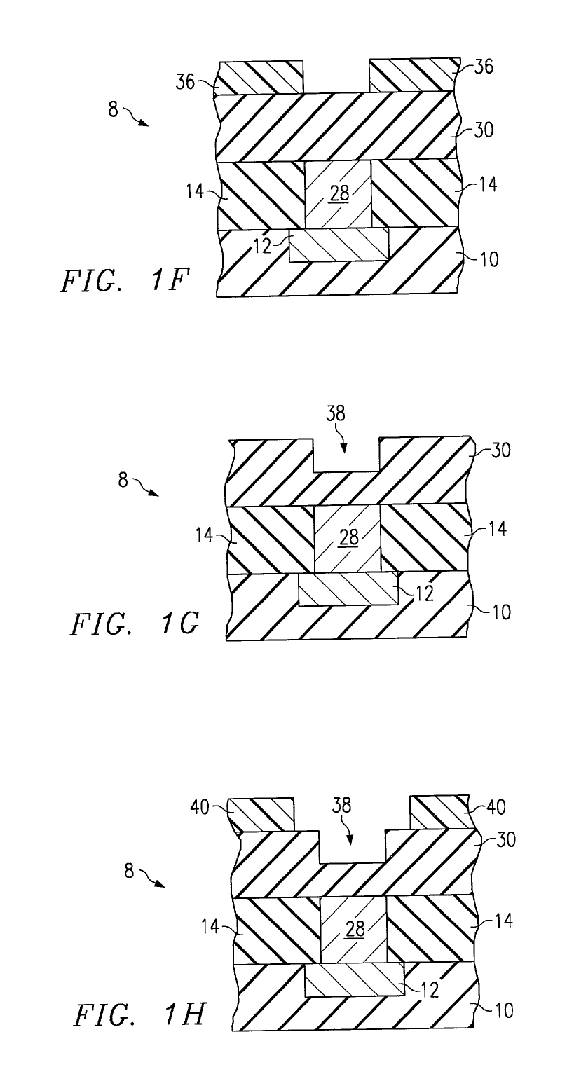

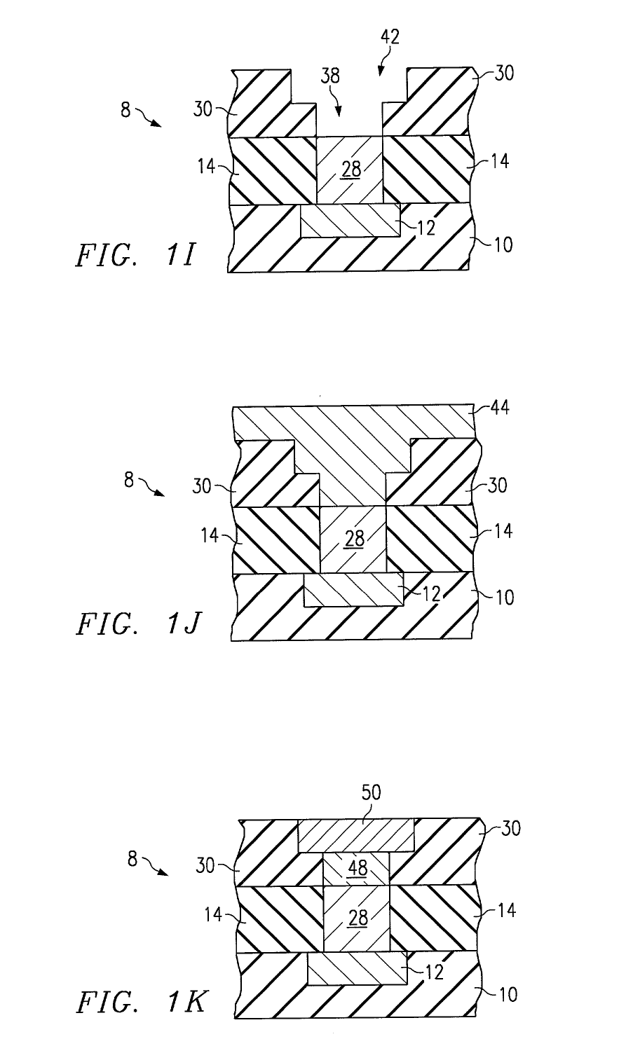

Referring to FIG. 1A, an initial structure 8 for an electronic circuit includes a first dielectric layer 10 comprising a interconnect element 12. It will be understood that the structure 8 may comprise a semiconductor wafer or other suitable structure (not shown in FIG. 1) as a base on which an integrated circuit may be formed. The first dielectric layer 10 may be deposited on the structure 8 by chemical vapor deposition or other suitable means. According to one embodiment, the first dielectric layer 10 comprises a silicon oxide. The first dielectric layer 10 may be about 40 to about 3,000 nm thick.

The interconnect element 12 may form part of a transistor, capacitor, resistor, interconnect or other suitable device which may be part of an integrated circuit. According to one embodiment, the interconnect element 12 comprises copper or other suitable conducting material.

The structure 8 also comprises a second dielectric layer 14. The second dielectric layer 14 comprises a via layer 14a and an interconnect layer 14b. The via layer 14a comprises a layer in which vias are conventionally formed. The interconnect layer 14b comprises a layer in which interconnect elements are conventionally formed. The layers 14a and 14b may comprise the same or different material and may or may not be separated by a stop layer (not shown in FIG. 1A) in order to allow separate processing of the two layers 14a and 14b.

Thus, conventional vias may be formed in appropriate locations within the via layer 14a and conventional interconnect elements may be formed in appropriate locations within the interconnect layer 14b. Each conventional via in the via layer 14a is encompassed by a interconnect element in the interconnect layer 14b. As described in more detail below, the present invention provides for forming a via that extends through both the via layer 14a and the interconnect layer 14b. Thus, the via is not coupled to a later formed via through a interconnect element in the interconnect layer 14b, but instead is directly coupled to the later formed via.

The second dielectric layer 14 may be deposited by chemical vapor deposition or other suitable means. According to one embodiment, the second dielectric layer 14 comprises a silicon oxide. For this embodiment, a stop layer between the via layer 14a and the interconnect layer 14b may comprise silicon nitride. The second dielectric layer 14 may be about 40 to about 3,000 nm thick.

Referring to FIG. 1B, a mask 16 is conventionally formed outwardly of the second dielectric layer 14. The mask 16, which comprises a material that is sensitive to light, is patterned through a process that generally includes photolithography and etching. The mask 16 forms a pattern that corresponds to the interconnect element 12 in the first dielectric layer 10 over which a stacked via is to be formed in accordance with the present invention. Although not shown in FIG. 1B, the mask 16 also forms a pattern corresponding to other interconnect elements in the first dielectric layer 10 over which conventional vias, if any, are to be formed in the via layer 14a.

Referring to FIG. 1C, the second dielectric layer 14 over the interconnect element 12 is removed by an etch process that is selective to the interconnect element 12, while remaining portions of the second dielectric layer 14 are protected by the mask 16. According to one embodiment, the etch is a plasma etch containing fluorine. This results in the formation of a first via opening 20 in the second dielectric layer 14. At this step, etching of openings for conventional vias included in the mask pattern 16 is also accomplished. After etching, the mask 16 is removed with a resist stripping process.

According to one embodiment, the first via opening 20 comprises an aspect ratio of approximately half of the aspect ratio of conventional vias formed in the via layer 14a. According to one embodiment, the aspect ratio is approximately two. However, it will be understood that the first via opening 20 may comprise any suitable aspect ratio appropriate for fill of a via. For example, an integrated circuit may comprise a minimum cross-sectional area for vias. The cross-sectional area of the first via opening 20 may be greater than the minimum cross-sectional area but less than a minimum size for interconnect patterns in the integrated circuit. According to one embodiment, the cross-sectional area of the first via opening 20 is twice the minimum cross-sectional area for vias in order to facilitate conducting fill of the first via opening 20.

Although not illustrated, another mask is formed to pattern interconnect elements in the interconnect layer 14b of the second dielectric layer 14. At this time, openings are formed in the interconnect layer 14b encompassing the conventional vias in the via layer 14a and openings are also formed in the interconnect layer 14b for general interconnects. The mask used for this step protects the first via opening 20 while the other via and interconnect element openings are formed.

Referring to FIG. 1D, a first conducting layer 24 is deposited on the structure 8 to fill the first via opening 20. The first conducting layer 24 also fills the openings for the conventional vias and for the interconnect elements. According to one embodiment, the first conducting layer 24 comprises copper or other suitable conducting material. Multiple layers of conducting material may also be used. For example, diffusion barriers such as titanium nitride may be used in addition to the copper or other suitable conducting material.

Referring to FIG. 1E, the first conducting layer 24 remaining over the second dielectric layer 14 is removed with a chemical mechanical polish, leaving a first via 28 where the first via opening 20 had been formed. Thus, the first via 28 is directly coupled to the interconnect element 12. As used herein, “directly coupled” means that there is no intervening component between the first via 28 and the interconnect element 12.

A third dielectric layer 30 is deposited over the second dielectric layer 14 and the first via 28. Similar to the second dielectric layer 14, the third dielectric layer 30 comprises a via layer in which vias are conventionally formed and an interconnect layer in which interconnect elements are conventionally formed. The via and metal layers may comprise the same or different material and may or may not be separated by a stop layer in order to allow separate processing of the two layers.

The third dielectric layer 30 may be deposited by chemical vapor deposition or other suitable means. According to one embodiment, the third dielectric layer 30 comprises a silicon oxide. For this embodiment, a stop layer between the via layer and the interconnect layer of the third dielectric layer 30 may comprise silicon nitride. The third dielectric layer 30 may be about 40 to about 3,000 nm thick.

Referring to FIG. 1F, a mask 36 is conventionally formed outwardly of the third dielectric layer 30. The mask 36, which comprises a material that is sensitive to light, is patterned through a process that generally includes photolithography and etching. The mask 36 forms a pattern that corresponds to the first via 28. The mask 36 also forms a pattern corresponding to interconnect elements in the interconnect layer 14b over which conventional vias are to be formed.

Referring to FIG. 1G, the third dielectric layer 30 over the first via 28 is removed by an etch process that may be selective to a stop layer in the third dielectric layer 30. According to one embodiment, the etch is a plasma etch containing fluorine. This results in the formation of a second via opening 38 in the third dielectric layer 30. The conventional vias over the interconnect elements are also etched at this point. After etching, the mask 36 is removed with a resist stripping process.

Referring to FIG. 1H, a mask 40 is conventionally formed outwardly of the third dielectric layer 30. The mask 40, which comprises a material that is sensitive to light, is patterned through a process that generally includes photolithography and etching. The mask 40 forms a pattern that corresponds to a interconnect element to be later formed in the third dielectric layer 30.

Referring to FIG. 1I, the third dielectric layer 30 over the first via 28 is removed by an etch process that is selective to the first via 28. According to one embodiment, the etch is a plasma etch containing fluorine. This results in the formation of the second via opening 38 in the via layer of the third dielectric layer 30 and in the formation of a interconnect opening 42 in the interconnect layer of the third dielectric layer 30. After etching, the mask 40 is removed with a resist stripping process.

Referring to FIG. 1J, a second conducting layer 44 is deposited on the structure 8 to fill the second via opening 38 and the interconnect opening 42. The second conducting layer 44 also fills the openings etched for the conventional vias over the interconnect elements. According to one embodiment, the second conducting layer 44 comprises copper or other suitable conducting material.

Referring to FIG. 1K, a chemical mechanical polish is used to remove the second conducting layer 44 over the third dielectric layer 30, leaving a second via 48 where the second via opening 38 had been formed in the via layer of the third dielectric layer 30 and leaving a second interconnect element 50 where the interconnect opening 42 had been formed in the interconnect layer of the third dielectric layer 30. Although the second via 48 and the second interconnect element 50 are shown as separate elements, it will be understood that these elements 48 and 50 are continuous in accordance with the conducting fill of FIG. 1J.

Thus, the second via 48 is directly coupled to the first via 28 in that there is no intervening interconnect element or other component between the two vias 28 and 48. The resulting structure 8 provides a stacked via to connect the interconnect element 12 to another component which may be formed over and coupled to the second via 48. Thus, because no interconnect element is patterned and etched in the interconnect layer 14b, the stacked via is reduced in size as compared to a conventional stacked via that includes a interconnect element between two vias. In this way, an integrated circuit may be formed with a reduced node capacitance and with an increased density as compared to an integrated circuit comprising conventional stacked vias.

It will be understood that a via etch stop layer, such as silicon nitride, may be included in the dielectric layers 10, 14 and 30. Also, in the dual damascene flow, the via etch may precede the interconnect trench etch or the interconnect trench etch may precede the via etch.

Although the present invention has been described with several embodiments, various changes and modifications may be suggested to one skilled in the art, including choice of dielectrics, conductors, etchants, and planarization techniques. It is intended that the present invention encompass such changes and modifications as fall within the scope of the appended claims.

What is claimed is:

1. A method for forming stacked vias in an integrated circuit, comprising:
providing a first dielectric layer comprising a interconnect element;
forming a second dielectric layer outwardly of the first dielectric layer, the second dielectric layer comprising a via layer and an interconnect layer;
forming a first via opening by removing a portion of the second dielectric layer to expose the interconnect element;
forming a first via in the first via opening; and
forming a second via outwardly of the first via, the second via directly coupled to the first via.

2. The method of claim 1, wherein the second dielectric layer is about 40 nm to about 1,000 nm thick.

3. The method of claim 1, wherein the second dielectric layer further comprises a stop layer between the via layer and the interconnect layer and wherein the via layer comprises a silicon oxide, the interconnect layer comprises a silicon oxide, and the stop layer comprises silicon nitride.

4. The method of claim 1, forming a first via opening by removing a portion of the second dielectric layer to expose the interconnect element comprising:
forming a mask exposing the interconnect element; and removing the second dielectric layer with an etch process.

5. The method of claim 1, the first via comprising an aspect ratio of approximately two.

6. The method of claim 1, forming a second via outwardly of the first via comprising:
forming a third dielectric layer outwardly of the first via;
forming a second via opening by removing a portion of the third dielectric layer to expose the first via; and
forming the second via in the second via opening.

7. The method of claim 6, wherein the third dielectric layer is about 40 nm to about 3,000 nm thick.

8. The method of claim 6, forming a second via opening by removing a portion of the third dielectric layer to expose the first via comprising:
forming a mask exposing the first via; and
removing the third dielectric layer with an etch process.

9. The method of claim 6, wherein the third dielectric layer comprises a silicon oxide.

10. A method for forming stacked vias in an integrated circuit, comprising:
providing a first dielectric layer comprising a interconnect element;
forming a second dielectric layer by forming a via layer outwardly of the first dielectric layer and forming an interconnect layer outwardly of the via layer;
forming a first via opening in the second dielectric layer, the first via opening extending through the second dielectric layer;
forming a first via in the first via opening, the first via directly coupled to the interconnect element; and
forming a second via outwardly of the first via, the second via directly coupled to the first via.

11. The method of claim 10, wherein the second dielectric layer is about 40 nm to about 3,000 nm thick.

12. The method of claim 10, wherein the second dielectric layer further comprises a stop layer between the via layer and the interconnect layer and wherein the via layer comprises a silicon oxide, the interconnect layer comprises a silicon oxide, and the stop layer comprises silicon nitride.

13. The method of claim 10, the first via comprising an aspect ratio of approximately two.

14. The method of claim 10, the integrated circuit comprising a minimum cross-sectional area for vias in the integrated circuit, the first via comprising a cross-sectional area of approximately twice the minimum cross-sectional area.

15. The method of claim 10, forming a second via outwardly of the first via comprising:
forming a third dielectric layer outwardly of the first via;
forming a second via opening in the third dielectric layer, the second via opening extending through the third dielectric layer; and
forming the second via in the second via opening.

16. The method of claim 15, wherein the third dielectric layer is about 40 nm to about 3,000 nm thick.

17. The method of claim 15, wherein the third dielectric layer comprises a silicon oxide.

18. An integrated circuit comprising a stacked via, the stacked via comprising:
a first via formed through a first dielectric layer, the first dielectric layer comprising a via layer and an interconnect layer and formed outwardly of a second dielectric layer comprising a interconnect element, the first via directly coupled to the interconnect element; and
a second via formed through a third dielectric layer formed outwardly of the first dielectric layer, the second via directly coupled to the first via.

19. The integrated circuit of claim 18, the first via comprising an aspect ratio of approximately two.

20. The integrated circuit of claim 18, the integrated circuit comprising a minimum cross-sectional area for vias in the integrated circuit, the first via comprising a cross-sectional area of approximately twice the minimum cross-sectional area.
